(19) United States
(12) Patent Application Publication
(10) Pub. No.: US 2002/0180627 A1
(43) Pub. Date: Dec. 5, 2002

(54) Automatic A/D sample triggering

(76) Inventor: Brian Boles, Mesa, AZ (US)

Correspondence Address: SWIDLER BERLIN SHEREFF FRIEDMAN, LLP, 3000 K STREET, NW, BOX IP, WASHINGTON, DC, 20007, US

(21) Appl. No.: 09/870,456

(22) Filed: Jun. 1, 2001

(51) Int. Cl. H03M 1/00

(52) U.S. Cl. 341/122

(57) ABSTRACT

A method and A/D module for automatically triggering analog to digital sampling and conversion are provided. The A/D module selects various analog signals for input. Up to four of the selected signals are sampled due to the initiation of a sampling operation. The A/D periodically polls for a heartbeat condition. Upon the occurrence of the heartbeat condition the sampling is ended and a conversion sequence is automatically started to convert the selected signals to binary representations. When the conversion sequence is completed the binary representation is stored to memory and sampling sequence is automatically started.

### BACKGROUND OF THE INVENTION

1. Field of the Invention

The present invention relates to systems and methods for analog to digital conversion and, more particularly, to systems and methods for automatically triggering analog to digital sample and conversion sequences.

2. Description of Prior Art

Processors, including microprocessors, digital signal processors and microcontrollers, operate by running software programs that are embodied in one or more series of instructions stored in a memory. The processors run the software by fetching instructions from the series of instructions, decoding the instructions and executing the instructions. The processors typically contain an analog to digital converter module, which, under control of the processor instructions, measures an analog input signal and provides a binary number representing that analog input signal for use by subsequent processor instructions. Processors, including digital signal processors, are conventionally adept at processing instructions that initiate analog to digital sampling and conversion sequences. For example, analog to digital sampling and conversion is controlled by instructions of an interrupt service routine (ISR) for an interrupt. The interrupt is launched by a signal, such as a heartbeat signal, generated by a heartbeat clock/timer. Typically, additional software instructions are required to control the coordination of sampling and conversion with the signal. This type of analog to digital sampling and conversion control requires multiple processor cycles and additional instructions and accordingly are inefficient.

There is a need for a new method of triggering analog to digital sampling and conversion within a processor that makes efficient use of processor cycles. There is a further need for a new method of triggering analog to digital sampling and conversion within a processor that does not require additional instructions. There is also a need for a new method of triggering analog to digital sampling and conversion within a processor that allows flexible selection of heartbeat signal sources. There is an additional need for a new method of triggering analog to digital sampling and conversion within a processor automatically. There is a need for a processor that triggers analog to digital sampling and conversion automatically, based on a heartbeat signal source, to more accurately coordinate the sample time with the selected heartbeat clock.

### SUMMARY OF THE INVENTION

According to embodiments of the present invention, methods and processors for automatically triggering analog to digital sampling and conversion are provided. This type of analog to digital sampling and conversion is triggered automatically employing hardware to coordinate with a heartbeat signal generated from a variety of sources.

According to an embodiment of the present invention, a method of automatically triggering analog to digital sampling and conversion includes connecting selected analog signals as input. The analog signals may originate from an external source. Sampling of a first set of selected analog signals is initiated. Upon determining that a heartbeat condition has occurred a conversion sequence is automatically initiated on an analog signal in the first set of selected analog signals. The first set of selected analog signals includes up to four analog signals.

The first set of analog signals may be sampled simultaneously or sequentially.

According to an embodiment of the present invention, upon determining that the sampling sequence is complete, a binary representation of the analog signal in the set of selected analog signals is stored to memory. The sampling sequence is automatically initiated upon completion of the conversion sequence.

According to an embodiment of the present invention, An A/D module for triggering analog to digital sampling and conversion includes input switch logic operable to connect selected analog signals as input. The analog signals may originate from an external source. The A/D module further includes sample/hold logic operable to initiate sampling of a first set of selected analog signals and an ADC unit operable to determine that a heartbeat condition has occurred and automatically initiate a conversion sequence on an analog signal in the first set of selected analog signals.

### BRIEF DESCRIPTION OF THE DRAWINGS

The above described features and advantages of the present invention will be more fully appreciated with reference to the detailed description and appended figures in which:

FIG. 1 depicts a functional block diagram of an embodiment of an analog to digital module within which embodiments of the present invention may find application;

FIG. 2 depicts a method of automatically triggering analog to digital sampling and conversion according to embodiments of the present invention;

FIGS. 3A-3B depict timing diagrams of example sample/conversion sequences according to embodiments of the present invention; and

FIGS. 4A-4B depict timing diagrams of example sample/conversion sequences according to embodiments of the present invention.

### DETAILED DESCRIPTION OF THE INVENTION

According to embodiments of the present invention, methods and processors for automatically triggering analog to digital sampling and conversion are provided. This type of analog to digital sampling and conversion is triggered automatically employing hardware to control the coordination of the digital sampling and conversion with a heartbeat signal generated from a variety of sources. The analog to digital sampling and conversion allows conversion of an analog input signal, such as a voltage, to a corresponding 10-bit digital number.

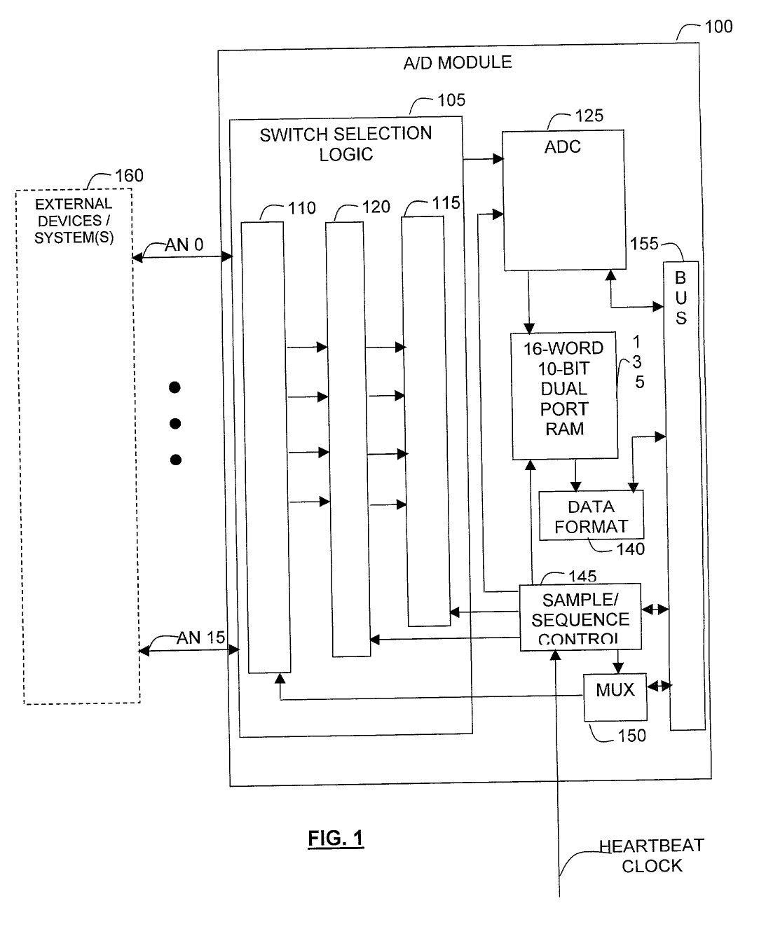

FIG. 1 depicts a functional block diagram of an embodiment of an A/D module within a processor in which the present invention may find application. Referring to FIG. 1, an A/D module 100 is coupled to external devices/systems 160. The A/D module may be within any type of a digital signal processor (DSP). The external devices 160 may be any type of systems or devices including input/output devices such as sensors, motion controllers, keyboards, displays, speakers, microphones, memory, or other systems which may or may not include processors.

The A/D module 100 includes switch selection logic 105, analog to digital converter (hereinafter “ADC”) 125, dual port ram 135, data formatter 140, sample/sequence controller 145 and input multiplexor control 150. A bus 155, which may include one or more common buses, communicates processor commands and data to and from ADC 125, data formatter 140, sample/sequence controller and input multiplexor control 150.

The sequence selection logic 105 includes input switch logic 110, channel switch logic 115 and sample/hold logic 120. Input switch logic 110 is coupled to input multiplexor control 150, external devices 160, and channel switch logic 115. Input switch logic 110 includes input switches that direct the sequence that the A/D module 100 connects outputs of external devices to inputs of sample/hold logic 120. The external devices 160 may generate and output analog signals, such as electrical voltage signals, for input to input sample/hold logic 120. The analog signals are input to sample hold logic 120 from the external devices 160 employing pins that extend from the input switches of input switch logic 110 to the exterior of the processor and couple to the external devices 160. For example, 16 pins may extend from the input switches of input switch logic 110 to the exterior of the processor and couple to the external devices 160. The pins may be multiplexed for input to sample/hold logic 115. The pins may include single ended and differential inputs.

Input switch logic 110 receives input sequence control signals in order to execute the connection of various analog signal inputs to sample/hold logic 120 in a specified sequence. The input multiplexor control 150 may cause input sequence control signals to be sent to input switches of input switch logic 110 to close the circuits associated with the input switch, thereby connecting the various analog signals output by external devices 160 to sample/hold logic 120. Alternatively, the input multiplexor control 150 may cause input sequence control signals to be sent to input switches of input switch logic 110 alternate between connection of a first group of analog signal and a second group of analog signals. The input sequence control signals sent by input multiplexor control 150 are based on an original input sequence control signal generated in accordance with sequence control bits, as specified by a programmer user and stored in a program control register (not shown). In the embodiment of FIG. 1, sample/sequence controller 145 generates the original signal. Connection bits in the sequence control bits specify the sequence that the A/D module 100 connects and inputs analog signals to sample/hold logic 120. An alternate bit in the sequence control bits specifies alternating between connection of groups of analog signals.

In the FIG. 1 embodiment of the present invention, sample/hold logic is coupled to input switch logic 110, channel switch logic 115 and a sample/sequence controller 145. The sample/hold logic 120 includes sample and hold amplifiers. For example, there may be up to four sample and hold amplifiers. The sample and hold amplifiers may connect to and input, up to four, various analog signals for sampling and produce analog signal sample outputs to ADC 125. The analog sample signal output by a sample and hold amplifier corresponds to the analog signal input to the sample and hold amplifier. The various analog signals connected and inputted to the sample and hold amplifiers are in accordance with sequence control bits specifying the various analog signals for connection and input to sample and hold amplifiers. The sample/hold logic 120 may employ one or more sample and hold amplifiers to perform sampling.

The sample/hold logic 120 may receive sample clock control signals that control the timing for connecting the various analog signals to sample and hold amplifiers in the selected sequence. The sample/sequence controller 145 generates the sample clock control signals in accordance with sample bits in the sequence control bits specifying the number of sample and hold amplifiers for employment.

In the FIG. 1 embodiment of the present invention, channel switch logic 115 is coupled to sample/hold logic 120, ADC 125 and a sample/sequence controller 145. Channel switch logic 115 includes channel switches that connect, in sequence, the various analog signal sample outputs of the sample/hold logic 120 for input to ADC 125. The channel switch logic 115 may receive channel sequence control signals in order to select the sequence for connecting the various analog signal sample outputs when multiple sample and hold amplifiers are selected. The various analog signal sample outputs may be connected from sample and hold amplifiers of sample/hold logic 120 to ADC 125 sequentially. The sample/sequence controller 145 generates the channel sequence control signals to be sent to channel switch logic 115 in accordance with channel bits specified in the sequence control bits.

The ADC 125 is coupled to bus 155, switch selection logic 105 and dual port ram 135. The ADC 120 receives as input analog signals output from sample and hold amplifiers and outputs binary representations of the input comparison electrical voltage signals. The ADC 125 performs sampling by comparing the various analog signals with a reference analog signal to generate a sample analog signals as well as converts the sample analog signals to produce binary representations based on the sample analog signal. Each binary representation corresponds to an analog signal input to channel switch logic 115. The conversion may be performed in response to the input of conversion start signals to ADC 125. A flag may be set indicating the start of a conversion. The completion of a conversion may be identified by the determination that the flag has been cleared and the determination of an interrupt condition.

The sample/sequence controller 145 generates and outputs conversion start signals to ADC 125 to suspend sampling by the sample and hold amplifiers and initiate conversion by conversion logic 125. The conversion start signal is generated in response to the input of a heartbeat signal to the sample/sequence controller 145. The heartbeat signal may be generated due to the occurrence of a variety of events. For example, the heartbeat signal may be generated due to a binary counter that increments each system cycle and external events, such as the determination of a specific voltage.

The dual port ram 135 is coupled to ADC 125, a data formatter 140 and sample/sequence controller 145. The dual port ram 135 receives 10-bit results and write signals as inputs and stores the 10-bit results at appropriate addresses. Binary representations may be provided as a 10-bit result and corresponds to the binary representation of an analog signal input to ADC 125. The dual port ram may be a 16-word 10-bit volatile memory. The dual port ram 135 stores a 10-bit result at an address specified by a write control signal. The sample/sequence controller 145 generates write control signals in accordance with write bits, as specified by a programmer user and stored in a program control register (not shown), and outputs the write control signals to dual port ram 135 as input. The data formatter converts the 10-bit results into different format 16-bit words.

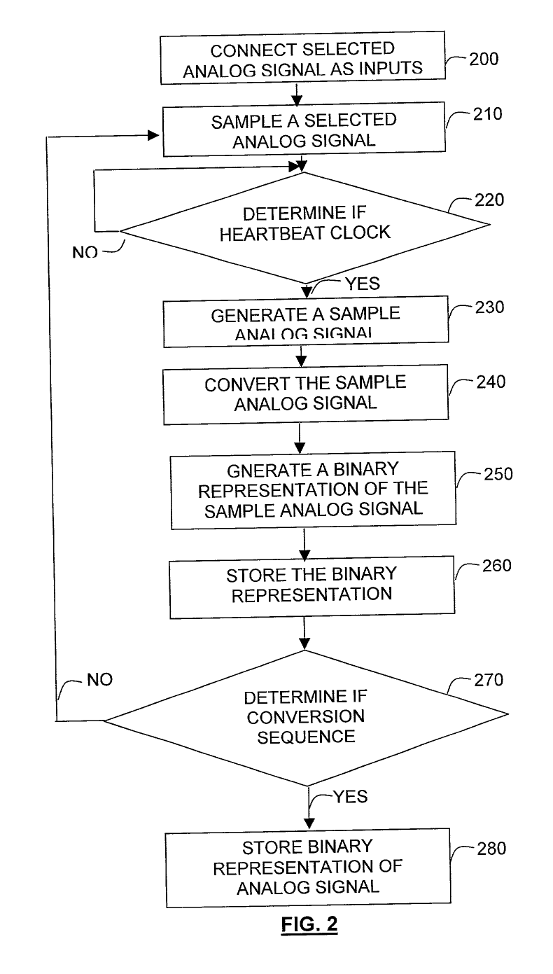

FIG. 2 depicts a method of automatically triggering analog to digital sampling and conversion according to embodiments of the present invention. FIG. 2 is best understood when viewed in conjunction with FIG. 1. Referring to FIG. 2, in step 200, the A/D module 100 connects selected analog signal inputs to input switch logic 110 for output to sample/hold amplifiers 120. The input may originate from a variety of external devices 160. Then in step 210, the A/D module samples a set of selected analog signals. Anywhere from one (1) to four (4) signals may be sampled. In step 220, the A/D module determines whether a heartbeat clock is generated. The heartbeat clock may be associated with a variety of events, both internal and external. If a heartbeat clock is generated the process proceeds to step 230. If a heartbeat clock is not generated the process returns to step 220. In step 230, the A/D module selects a sample analog signal. Then in step 240, the A/D module 100 converts the sample analog signal. Then in step 250, the A/D module generates a binary representation of the sample analog signal. The binary representation of the sample analog signal may be provided as 10-bits. In step 260, the A/D module 100 stores the binary representation. In step 270, the A/D module determines whether the conversion sequence is complete. If the conversion is complete process proceed to step 280. If the conversion is not complete the process returns to step 210. In step 270, the A/D stores the binary representations of the set of analog signals. The binary representation may be stored in a 16-word 10-bit dual port ram. The binary representations of the set of analog signals may be formatted for delivery using a communication bus.

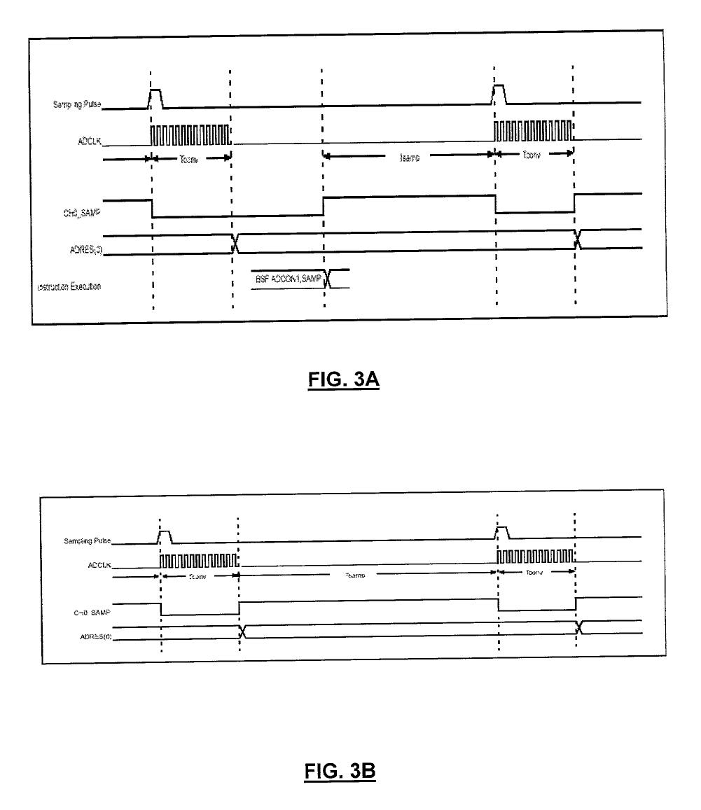

FIGS. 3A-3B depict timing diagrams of example sample/conversion sequences according to embodiments of the present invention. In the embodiment of FIG. 3A, the timing diagram illustrates selecting a timer as the conversion start signal (hereinafter “sampling pulse”). The sampling end and conversion start occurs with the rising edge of the sample pulse. Software instructions initiate sampling, while sample pulse ends sampling and starts conversion. In the embodiment of FIG. 3B, the timing diagram is similar to the timing diagram of FIG. 3A. The timing diagram illustrates selecting a timer as the sample pulse. The conversion start occurs with the rising edge of the sample pulse and the sampling start automatically occurs at the end of sampling. No software instructions are employed to initiate sampling.

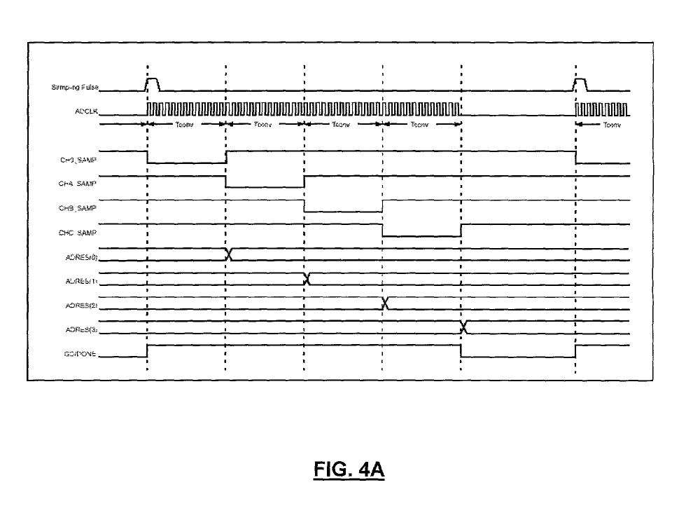

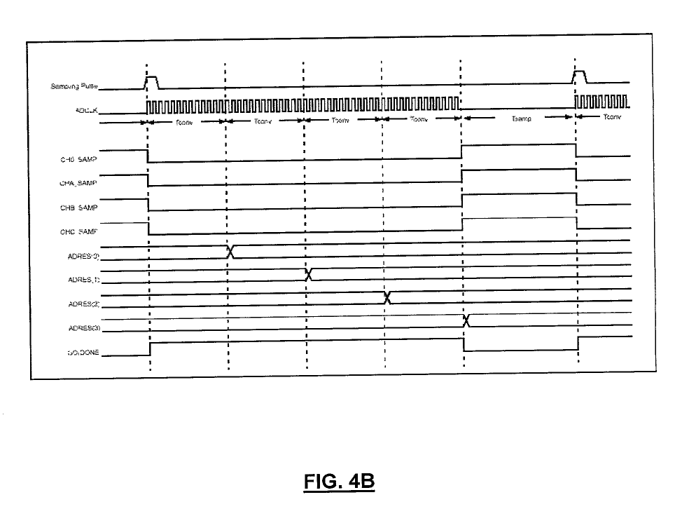

FIGS. 4A-4B depict timing diagrams of example sample/conversion sequences according to embodiments of the present invention. In the embodiment of FIG. 4A, the timing diagram illustrates the A/D module employing four (4) sample and hold amplifiers. A timer provides the sample clock and starts conversion sequence for each of the signals provided by the sample and hold amplifiers. The sampling is initiated automatically upon the completion of the conversion sequence for all channels. In the embodiment of FIG. 4B, the timing diagram illustrates the A/D module employing four (4) sample and hold amplifiers. A timer provides the sample clock and starts conversion sequence for each of the signals provided by the sample and hold amplifiers. The sampling is initiated automatically upon the completion of the conversion sequence for each channel.

While specific embodiments of the present invention have been illustrated and described, it will be understood by those having ordinary skill in the art that changes may be made to those embodiments without departing from the spirit and scope of the invention.

What is claimed is:

1. A method of automatically triggering analog to digital sampling and conversion, comprising:
connecting selected analog signals as input, the analog signals originating from an external source;
initiating sampling of a first set of selected analog signals;
determining that a heartbeat condition has occurred, the heartbeat condition operable to automatically initiate a conversion sequence; and
initiating the conversion sequence on an analog signal in the first set of selected analog signals.

2. The method according to claim 1, wherein the first set of selected analog signals includes up to four analog signals.

3. The method according to claim 2, wherein the first set of analog signals are sampled simultaneously.

4. The method according to claim 2, wherein the first set of analog signals are sampled sequentially.

5. The method according to claim 1, wherein the heartbeat condition is generated internally.

6. The method according to claim 1, wherein the heartbeat condition is generated externally.

7. The method according to claim 1, further comprising determining that the conversion sequence has completed.

8. The method according to claim 7, further comprising storing a binary representation of the analog signal in the set of selected analog signals.

9. The method according to claim 8, further comprising automatically initiating sampling of a second set of selected analog signals.

10. An A/D module for triggering analog to digital sampling and conversion, comprising:
an input switch logic operable to connect selected analog signals as input, the analog signals originating from an external source;
a sample/hold logic operable to initiate sampling of a first set of selected analog signals;
an ADC unit operable to:
determine that a heartbeat condition has occurred, the heartbeat condition operable to automatically initiate a conversion sequence; and
initiate the conversion sequence on an analog signal in the first set of selected analog signals.

11. The A/D module according to claim 10, wherein the first set of selected analog signals includes up to four analog signals.

12. The A/D module according to claim 11, wherein the first set of analog signals are sampled simultaneously.

13. The A/D module according to claim 11, wherein the first set of analog signals are sampled sequentially.

14. The A/D module according to claim 1, wherein the heartbeat condition is generated internally.

15. The A/D module according to claim 1, wherein the heartbeat condition is generated externally.

16. The A/D module according to claim 1, further comprising determining that the conversion sequence has completed.

17. The A/D module according to claim 16, further comprising storing a binary representation of the analog signal in the set of selected analog signals.

18. The A/D module according to claim 17, further comprising automatically initiating sampling of a second set of selected analog signals.
